(19) United States
(12) Patent Application Publication
(10) Pub. No.: US 2022/0034939 A1
(43) Pub. Date: Feb. 3, 2022

(54) METHOD AND APPARATUS FOR JUDGING ABNORMALITY OF PROBE CARD

(71) Applicant: CHANGXIN MEMORY TECHNOLOGIES, INC., Hefei City (CN)

(72) Inventor: CHENG-JER YANG, Hefei (CN)

(73) Assignee: CHANGXIN MEMORY TECHNOLOGIES, INC., Hefei City (CN)

(21) Appl. No.: 17/445,630

(22) Filed: Aug. 23, 2021

Related U.S. Application Data
(63) Continuation of application No. PCT/CN2021/101399, filed on Jun. 22, 2021.

(30) Foreign Application Priority Data
Jul. 28, 2020 (CN) 202010735661.4

(51) Int. Cl. G01R 1/073; G01R 31/28

(52) U.S. Cl. CPC G01R 1/07342; G01R 31/2891

(57) ABSTRACT

A method for judging abnormality of a probe card includes: a unit failure rate of chips at the same test position in each measurement unit is obtained, and whether the unit failure rate of the chips at the same test position respectively meets the first abnormality condition is judged; when the unit failure rate of the chips at the same test position of each measurement unit meets a first abnormality condition, whether a test sequence for the measurement units meeting the first abnormality condition meets a second abnormality condition is judged; and when the test sequence for the measurement units meeting the first abnormality condition meets the second abnormality condition, it is determined that the probe card is abnormal.

### CROSS-REFERENCE TO RELATED APPLICATIONS

The present application is a continuation of International Application No. PCT/CN2021/101399 filed on Jun. 22, 2021, which claims priority to Chinese Patent Application No. 202010735661.4 filed on Jul. 28, 2020. The disclosures of these applications are hereby incorporated by reference in their entirety.

### BACKGROUND

An integrated circuit is formed by integrating elements, such as semiconductors, resistors, capacitors, etc., required for circuits with certain functions and the required connecting wires on a substrate through a semiconductor manufacturing process such as oxidation, photolithography, diffusion, epitaxy and thin film deposition, etc. With the rapid development of an integrated circuit technology, modern integrated circuits have developed into very large integrated circuits. Therefore, for integrated circuit chips, before cutting into single chips from a wafer, each chip must be tested to ensure that its integrated circuit component specifications meet the standard, and the test is usually performed by probe card equipment.

### SUMMARY

The present application relates generally to the technical field of semiconductors, and more specifically to a method and apparatus for judging abnormality of a probe card.

One aspect of the present application provides a method for judging abnormality of a probe card, including: measurement units are selected, and a unit failure rate of chips at the same test position in each measurement unit is obtained respectively; whether the unit failure rate of the chips at the same test position in each measurement unit respectively meets a first abnormality condition is judged; when the unit failure rate of the chips at the same test position in any one measurement unit meets the first abnormality condition, whether a test sequence for the measurement units meeting the first abnormality condition meets a second abnormality condition is judged; and when the test sequence for the measurement units meeting the first abnormality condition meets the second abnormality condition, it is determined that the probe card is abnormal.

Another aspect of the present application provides an apparatus for judging abnormality of a probe card, including a processor and a memory. The memory is configured to store computer programs capable of running on the processor, and the processor is configured to call and run the computer programs stored in the memory to select measurement units and obtain a unit failure rate of chips at the same test position in each measurement unit respectively; judge whether the unit failure rate of the chips at the same test position of each measurement unit meets a first abnormality condition; judge whether a test sequence for the measurement units meeting the first abnormality condition meets a second abnormality condition when the unit failure rate of the chips at the same test position of any one measurement unit meets the first abnormality condition; and determine that the probe card is abnormal when the test sequence for the measurement units meeting the first abnormality condition meets the second abnormality condition.

The details of the various embodiments of the present disclosure will be illustrated in the following drawings and description. Based on the description, drawings and claims, those skilled in the art will easily understand other features, problems to be solved, and beneficial effects of the present disclosure.

### BRIEF DESCRIPTION OF THE DRAWINGS

In order to more clearly describe the technical solutions in the embodiments of the present application or the traditional technology, the following will briefly introduce the drawings to be used in the description of the embodiments or the traditional technology, and the additional details or examples used to describe the drawings should not be considered as a limitation on the scope of any one of the invention, the currently described embodiments, or the preferred manners of the present application.

FIG. 1 is a flowchart of a method for judging abnormality of a probe card provided by embodiments of the present application;

FIG. 2 is a schematic diagram of a failed chip position in a wafer in a method for judging abnormality of a probe card provided by embodiments of the present application; and

FIG. 3 is a schematic diagram of a plurality of measurement units in a method for judging abnormality of a probe card provided by embodiments of the present application.

### DETAILED DESCRIPTION

For convenience of an understanding of the present application, the present application will now be described more fully hereinafter with reference to the related drawings. The preferred embodiments of the present application are shown in the accompanying drawings. The present application may, however, be embodied in many different forms which are not limited to the embodiments described herein. Rather, these embodiments are provided so that the disclosure of the present application will be thorough and comprehensive.

Unless defined otherwise, all technical and scientific terms used herein have the same meaning as commonly understood by those skilled in the art to which the present application belongs. The terms used herein in the specification of the present application are for the purpose of describing specific embodiments only and are not intended to be limiting of the present application.

As used herein, the singular forms “a/an”, “one”, and “the” may include the plural forms as well, unless the context clearly dictates otherwise. It should also be understood that when the terms “compose” and/or “comprise” are used in the specification, the presence of the described features, integers, steps, operations, elements and/or components may be determined, but the presence or addition of one or more other features, integers, steps, operations, elements, components and/or groups is not excluded. At the same time, when used herein, the term “and/or” includes any and all combinations of related listed items.

In the semiconductor manufacturing process, the probe card equipment used for wafer testing is usually overhauled regularly, and defect management tools are used for quality testing after the overhaul. If the overhauled probe card equipment meets the quality test requirements, the probe card equipment is released; and if the probe card equipment is not overhauled in time, the yield loss is caused by poor testing.

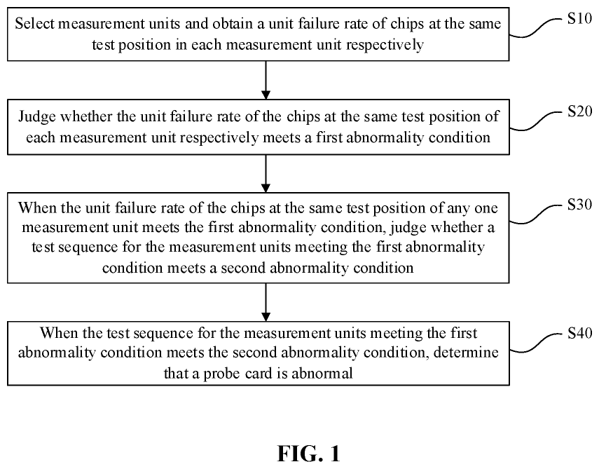

Referring to FIG. 1, various embodiments the present application provide a method for judging abnormality of a probe card, including the following steps.

At step S10, measurement units are selected, and a unit failure rate of chips at the same test position in each measurement unit is obtained respectively.

At step S20, whether the unit failure rate of the chips at the same test position of each measurement unit respectively meets a first abnormality condition is judged;

At step S30, when the unit failure rate of the chips at the same test position of any one measurement unit meets the first abnormality condition, whether a test sequence between the measurement units that meet the first abnormality condition meets a second abnormality condition or not is judged; and

At step S40, when the test sequence for the measurement units meeting the first abnormality condition meets the second abnormality condition, it is determined that the probe card is abnormal.

According to the method for judging the abnormality of the probe card provided by the present application, the unit failure rate of the chips at the same test position in each measurement unit is obtained, whether the unit failure rate of the chips at the same test position of each measurement unit respectively meets the first abnormality condition is judged, and the possible abnormal positions in the probe card may be screened out to make a preliminary judgment on whether the probe card is abnormal. If the unit failure rate of the chips at the same test position of any one measurement unit meets the first abnormality condition, whether the test sequence for the measurement units meeting the first abnormality condition meets the second abnormality condition is judged, that is, the possible abnormal positions in the probe card are further judged. If the test sequence for the measurement unit meeting the first abnormality condition meets the second abnormality condition, it is determined that the probe card is abnormal. Therefore, the above method for judging the abnormality of the probe card may combine the unit failure rate at the same test position in each measurement unit, the first abnormality condition and the second abnormality condition, and realize the monitoring and analysis of the abnormality condition of the probe card, thus the probe card may be overhauled in time, and the yield loss caused by poor testing is reduced.

It should be understood that although the steps of the flowchart in FIG. 1 are shown sequentially as indicated by the arrows, the steps are not necessarily performed sequentially as indicated by the arrows. According to recording of the present invention, those skilled in the art will understand that these steps may further be executed according to other sequences. Moreover, at least a portion of the steps in FIG. 1 may include multiple steps or phases that are not necessarily performed at the same time, but may be performed at different times, and the steps or phases are not necessarily performed in sequence, but rather may be performed in turns or alternation with other steps or at least a portion of the steps or phases in the other steps.

In one of the embodiments, the step S10, i.e., the measurement units are selected and the unit failure rate of the chips at the same test position in each measurement unit is obtained respectively, includes the following steps.

At step S110, the measurement units are selected, and failed chips in each measurement unit are respectively detected;

At step S120, the number of the failed chips at the same test position in each measurement unit is obtained; and

At step S130, the unit failure rate of the chips at the same position in each measurement unit is calculated according to the number of the failed chips at the same test position in each measurement unit and the number of all tested chips at the same test position.

In one of the embodiments, at step S110, the measurement units may be selected firstly, in which each measurement unit may include one or more wafers, and the number of the wafers in different measurement units may be the same or different. In the embodiment, each measurement unit may include a batch of wafers, and the number and specifications of the wafers in each measurement unit may be the same.

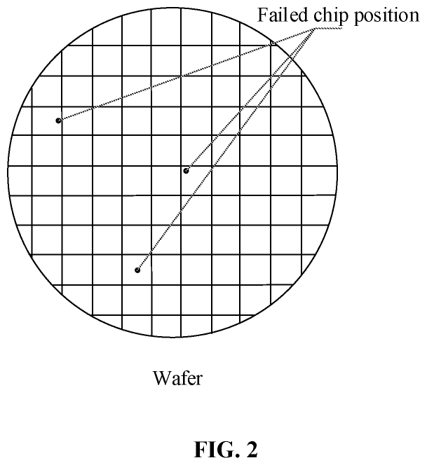

Further referring to FIG. 2, in one of the embodiments, at step S110, a to-be-tested probe card may be adopted to sequentially detect chips of each wafer in each measurement unit to obtain all failed chips in each measurement unit. An apparatus for judging abnormality of the probe card or a probe card monitoring system may monitor detection data in real time during the chip detection process. When the to-be-tested probe card is adopted to sequentially detect the chips in each measurement unit, the order of the chip detection may be set according to actual needs. In the embodiment, the chips in each wafer in each measurement unit may be detected column by column or row by row.

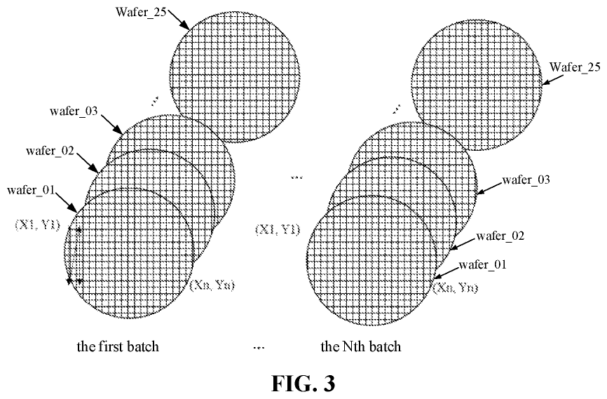

Further referring to FIG. 3, in one of the embodiments, at step S110, in the process of sequentially detecting the chips in each measurement unit, a position of each chip may be marked. In the embodiment, positions of the chips in each wafer may be marked by adopting coordinates. Specifically, in a wafer, the position of the chip in the first column and the first row may be (X1, Y1), the position of a chip in the first column and second row may be (X1, Y2), . . . , the position of a chip in the second column and the first row may be (X2, Y1), the position of a chip in the second column and second row may be (X2, Y2), and so on. When the to-be-tested probe card detects that the chip at a certain coordinate position is a failed chip, the position (Xi, Yj) of the failed chip may be obtained, in which i=1 . . . N and j=1 . . . M, N is the column number of the chips on each wafer, and M is the row number of the chips on each wafer. N and M may be equal or different.

In one of the embodiments, at step S120, if the position of the failed chip is (Xi, Yj), by judging whether the chips at the same test position (Xi, Yj) of each wafer of the current measurement unit are failed chips, the number of the failed chips at the same test position (Xi, Yj) in the current measurement unit may be obtained.

In one of the embodiments, a first wafer in a first measurement unit may be selected, and the chip (X1, Y1) in the first wafer may be detected so as to judge whether the chip (X1, Y1) fails. If the chip (X1, Y1) fails, Count (X1, Y1) +1, that is, the number of the failed chips at the same test position (X1, Y1) is increased by 1. Subsequently, a second wafer in the first measurement unit may be selected, and the chip (X1, Y1) in the second wafer may be detected so as to judge whether the chip (X1, Y1) fails. If the chip (X1, Y1) fails, Count (X1, Y1) +1, until the chips (X1, Y1) of all wafers are detected. In addition, the above steps may be repeated until the detection of chips at all positions of all wafers in the first measurement unit is completed, and the number of the failed chips at each same test position in the first measurement unit is counted respectively.

In one of the embodiments, at step S130, in each measurement unit, the unit failure rate of each same test position is the ratio of the number of the failed chips at the same test position to the number of all tested chips at the same test position. In one of the embodiments, the number of the failed chips at the same test position (Xi, Yj) in a certain measurement unit may be 21, the number of all tested chips at the same test position (Xi, Yj) may be 25, and then it may be calculated that the unit failure rate of the measurement unit at the same test position (Xi, Yj) is 21/25×100%=84%.

In one of the embodiments, step S20, i.e., whether the unit failure rate of the chips at the same test position of each measurement unit respectively meets the first abnormality condition is judged includes the following steps.

At step S210, whether the unit failure rate of the chips at the same test position of each measurement unit is greater than or equal to a preset failure rate threshold is judged.

At step S220, if the unit failure rate of the chips at the same test position of each measurement unit is greater than or equal to the preset failure rate threshold, it is determined that the unit failure rate of the chips at the same test position of each measurement unit meets the first abnormality condition.

In one of the embodiments, at step S210, whether the unit failure rate of the chips at the same test position in each measurement unit is greater than or equal to the preset failure rate threshold may be judged, thereby simplifying the judgment process of whether each measurement unit meets the first abnormality condition. In one of the embodiments, the preset failure rate may be 50%-70%. The specific preset failure rate threshold may be set according to actual conditions. In the embodiment, the preset failure rate threshold may be 60%.

In one of the embodiments, at step S220, in each measurement unit, if there is a unit failure rate of chips at a same test position in the wafer that is greater than the preset failure rate threshold, the possibility that the probe card is abnormal exists. Hence , as long as there is one unit failure rate of the chips at the same test position in each measurement unit that is greater than the preset failure rate threshold, it may be determined that the unit failure rate of the chips at the same test position in each measurement unit meets the first abnormality condition, and thus misjudgment of the abnormal situation of the probe card is avoided. In another embodiment, there may also be a situation that the unit failure rates of chips at a plurality of same test positions meet the first abnormality condition in each measurement unit. At this time, it is necessary to further judge whether each measurement unit meeting the first abnormality condition meets the second abnormality condition for each same test position, so as to further judge whether the probe card at each same test position is abnormal. Therefore, the first abnormality condition may reflect a repeated failure probability of the chips at one or more same positions in a certain measurement unit, and may screen out the possible abnormal positions of the probe card so as to make a preliminary judgment on whether the probe card is abnormal.

In one of the embodiments, after step S20, i.e., whether the unit failure rate of the chips at the same test position of each measurement unit respectively meets the first abnormality condition is judged, the method further includes the following steps.

At step S201, when the unit failure rate of the chips at the same test position of any one measurement unit meets the first abnormality condition, the same test position is recorded as a chip failure position.

In one of the embodiments, at step S201, the possible abnormal position of the probe card may be screened out according to the first abnormality condition, so as to make a preliminary judgment on the abnormal situation of the probe card. Therefore, if the unit failure rate of the chips at the same test position meets the first abnormality condition, it means that in the current measurement unit, the failure rate of the chips at the same position is high, which may be caused by the abnormality of the probe card but not the process problem. At this time, the same test position may be recorded as the chip failure position. The chip failure position may be configured to lock the possible abnormal position of the probe card, so that after the abnormality judgment of the entire probe card is completed, the abnormal position of the probe card is overhauled in a targeted mode, the overhauling efficiency is improved, and the yield loss caused by poor testing is reduced.

In one of the embodiments, during the judgment of the second abnormality condition, the number of wafers in each measurement unit may be 25, that is, the number of all tested chips at the same test position is 25. A test position (Xi, Yj) is one of the chip failure positions. At this time, if the number of failed chips at the same test position (Xi, Yj) in a first measurement unit is 21, the number of failed chips at the same test position (Xi, Yj) in a second measurement unit is 16, and the number of failed chips at the same test position in a third measurement unit is 15, the unit failure rates of the three measurement units at the same test position (Xi, Yj) are 84%, 64% and 60% in sequence, that is, all are greater than or equal to the preset failure rate threshold 60%. When the test sequences of the first measurement unit, the second measurement unit and the third measurement unit are continuous, that is, the test time is adjacent to one another, it may be determined that the probe card is abnormal.

In one of the embodiments, step S30, i.e., whether the test sequence for the measurement units meeting the first abnormality condition meets the second abnormality condition is judged includes the following steps.

At step S310, the number of measurement units meeting the first abnormality condition is obtained.

At step S320, whether the number is greater than or equal to a preset number threshold for measurement unit is judged.

At step S330, when the measurement unit number is greater than or equal to the preset number threshold for measurement unit, it is determined that the test sequence for the measurement units meeting the first abnormality condition meets the second abnormality condition.

In one of the embodiments, at step S310, whether the unit failure rate of the chips at the same test position (Xi, Yj) in each measurement unit is greater than or equal to the failure rate threshold, that is, whether meets the first abnormality condition may be sequentially judged. If the unit failure rate of the chips at the same test position (Xi, Yj) of a certain measurement unit meets the first abnormality condition, the number of measurement units meeting the first abnormality condition is increased by 1, until all measurement units are judged, so as to count the number of measurement units meeting the first abnormality condition.

In one of the embodiments, at step S320 and step S330, by judging whether the number of measurement units meet the first abnormality condition and with a continuous test sequence is greater than or equal to the preset number threshold for measurement unit, whether the test sequence for the measurement units meeting the first abnormality condition meets the second abnormality condition or not may be judged. In one the embodiments, the measurement unit number of each measurement unit that meets the first abnormality condition may be 6, and the preset number threshold for measurement unit may be 4. When in the second measurement unit, the third measurement unit, the fourth measurement unit and the fifth measurement unit, i.e., the four measurement units with continuous test sequences, the unit failure rates of the chips at the same test position all meet the first abnormality condition, it may be determined that the probe card of a machine for wafer testing is abnormal.

In one of the embodiments, when there is a chip failure position in only one measurement unit, a misjudgment may be made on the abnormal situation of the probe card. Therefore, a plurality of measurement units may be selected to verify the abnormal situation of the probe card, that is, whether the number of the plurality of measurement units with continuous test sequences is greater than or equal to the preset number threshold for measurement unit is judged. In one of the embodiments, the present number threshold for measurement unit may be 3, that is, by judging the unit failure rates at the same test position of at least three measurement units that are continuously machined by the machine, the misjudgment of the abnormality of the probe card may be avoided, and the accuracy of the method for judging the abnormality of the probe card is improved.

In one of the embodiments, after it is determined that the probe card is abnormal, an alarm signal may be generated and sent to a preset terminal device. The type of the alarm signal may be set according to actual needs. In the embodiment, the alarm signal may be an abnormal pop-up window of the probe card sent to the terminal device to remind staff to overhaul the probe card. At the same time, the probe card abnormality judging apparatus may also generate a stop signal after it is determined that the probe card is abnormal, and send the stop signal to the machine where the probe card is located, so as to control the machine where the probe card is located to be shut down and wait for the staff to overhaul. Therefore, the generation of the alarm signal and the stop signal may ensure the timely overhauling of the probe card, thereby avoiding the yield loss.

Based on the same inventive concept, the present application further provides an apparatus for judging abnormality of a probe card, including: a unit failure rate obtaining unit, a first abnormality condition judging unit, a second abnormality condition judging unit and a probe card abnormality judging unit. The unit failure rate obtaining unit is configured to select measurement units and obtain a unit failure rate of chips at the same test position in each measurement unit respectively. The first abnormality condition judging unit is configured to judge whether the unit failure rate of the chips at the same test position of each measurement unit respectively meets a first abnormality condition. The second abnormality condition judging unit is configured to judge whether a test sequence for the measurement units meeting the first abnormality condition meets a second abnormality condition when the unit failure rate of the chips at the same test position of any one measurement unit meets the first abnormality condition. The probe card abnormality judging unit is configured to determine that the probe card is abnormal when the test sequence for the measurement units meeting the first abnormality condition meets the second abnormality condition.

In the apparatus for judging the abnormality of the probe card provided by the present application, the unit failure rate obtaining unit may obtain the unit failure rate of the chips at the same test position in each measurement unit, the first abnormality condition judging unit may judge whether the unit failure rate of the chips at the same test position of each measurement unit respectively meets the first abnormality condition, that is, possible abnormal positions in the probe card are screened out, so as to make a preliminary judgment on whether the probe card is abnormal. If the unit failure rate of the chips at the same test position of any one measurement unit meets the first abnormality condition, the second abnormality condition judging unit may judge whether a test sequence for the measurement units meeting the first abnormality condition meets the second abnormality condition, that is, the possible abnormal positions of the probe card are further judged. If the test sequence for the measurement units meeting the first abnormality condition meets the second abnormality condition, the probe card abnormality judging unit determines that the probe card is abnormal. Therefore, the above-mentioned apparatus for judging the abnormality of the probe card may combine the unit failure rate of each measurement unit at the same test position, the first abnormality condition and the second abnormality condition, and realize the monitoring and analysis of the abnormal situation of the probe card, so that the probe card may be overhauled in time, and the yield loss caused by poor testing is reduced.

In one of the embodiments, the unit failure rate obtaining unit includes: a failed chip detection subunit, a failed chip number counting subunit and a unit failure rate calculating subunit. The failed chip detection subunit is configured to select the measurement units and detect failed chips in each measurement unit respectively. The failed chip number counting subunit is configured to obtain the number of the failed chips at the same test position in each measurement unit. The unit failure rate calculating subunit is configured to calculate the unit failure rate of the chips at the same test position in each measurement unit according to the number of the failed chips at the same test position in each measurement unit and the number of all tested chips at the same test position.

In one of the embodiments, the first abnormality condition judging unit includes: a threshold judging subunit and a first abnormality condition judging subunit. The threshold judging subunit is configured to judge whether the unit failure rate of the chips at the same test position of each measurement unit is greater than or equal to a preset failure rate threshold. The first abnormality condition judging subunit is configured to determine that the unit failure rate of the chips at the same test position of each measurement unit meets the first abnormality condition when the unit failure rate of the chips at the same test position of each measurement unit is greater than or equal to the preset failure rate threshold.

In one of the embodiments, the second abnormality condition judging unit includes: a test sequence obtaining subunit, a test sequence judging subunit and a second abnormality condition judging subunit. The test sequence obtaining subunit is configured to obtain a test sequence of each measurement unit that meets the first abnormality condition. The test sequence judging subunit is configured to judge whether the test sequence is continuous. The second abnormality condition judging subunit is configured to determine that the test sequence for the measurement units meeting the first abnormality condition meets the second abnormality condition when the test sequence is continuous.

It should be noted that the functions of each unit of the apparatus for judging the abnormality of the probe card provided by the above embodiment may be the same as the description of the method for judging the abnormality of the probe card correspondingly, which will not be repeated here.

In some embodiments, another apparatus for judging abnormality of a probe card is provided. The apparatus comprises a processor and a memory. The memory is configured to store computer programs capable of running on the processor, and the processor is configured to call and run the computer programs stored in the memory to perform the steps of the method mentioned above.

The technical features of the above embodiments can be combined arbitrarily. In order to make the description concise, all possible combinations of various technical features in the above embodiments are not completely described. However, as long as there is no contradiction in the combination of these technical features, it should be regarded as the scope of this specification.

The foregoing embodiments represent only a few implementations of the present application, and the descriptions are specific and detailed, but should not be construed as limiting the patent scope of the present application. It should be noted that those of ordinary skill in the art may further make variations and improvements without departing from the conception of the present application, and these all fall within the protection scope of the present application. Therefore, the patent protection scope of the present application should be subject to the appended claims.

What is claimed is:

1. A method for judging abnormality of a probe card, comprising:
selecting measurement units, and obtaining a unit failure rate of chips at a same test position in each measurement unit respectively;
judging whether the unit failure rate of the chips at the same test position of each measurement unit respectively meets a first abnormality condition;
when the unit failure rate of the chips at the same test position of any one measurement unit meets the first abnormality condition, judging whether a test sequence for measurement units meeting the first abnormality condition meets a second abnormality condition; and
when the test sequence for the measurement units meeting the first abnormality condition meets the second abnormality condition, determining that the probe card is abnormal.

2. The method for judging the abnormality of the probe card of claim 1, wherein said selecting the measurement units and obtaining the unit failure rate of the chips at the same test position in each measurement unit respectively comprises:
selecting the measurement units and detecting failed chips in each measurement unit respectively;
obtaining a number of the failed chips at the same test position in each measurement unit; and
calculating the unit failure rate of the chips at the same test position in each measurement unit according to the number of the failed chips at the same test position in each measurement unit and a number of all tested chips at the same test position.

3. The method for judging the abnormality of the probe card of claim 1, wherein said judging whether the unit failure rate of the chips at the same test position of each measurement unit respectively meets the first abnormality condition comprises:
judging whether the unit failure rate of the chips at the same test position of each measurement unit is greater than or equal to a preset failure rate threshold; and
when the unit failure rate of the chips at the same test condition of each measurement unit is greater than or equal to the preset failure rate threshold, determining that the unit failure rate of the chips at the same test position of each measurement unit meets the first abnormality condition.

4. The method for judging the abnormality of the probe card of claim 1, wherein the second abnormality condition is that the test sequence for the measurement units is continuous.

5. The method for judging the abnormality of the probe card of claim 4, wherein said judging whether the test sequence for the measurement units meeting the first abnormality condition meets the second abnormality condition comprises:
obtaining a number of the measurement units meeting the first abnormality condition;
judging whether the number is greater than or equal to a preset number threshold for measurement unit; and
when the number is greater than or equal to the preset number threshold for measurement unit, determining that the test sequence for the measurement units meeting the first abnormality condition meets the second abnormality condition.

6. The method for judging the abnormality of the probe card of claim 1, wherein after said judging whether the unit failure rate of the chips at the same test position of each measurement unit respectively meets the first abnormality condition, the method further comprises:
when the unit failure rate of the chips at the same test position of any one measurement unit meets the first abnormality condition, recording the same test position as a chip failure position.

7. An apparatus for judging abnormality of a probe card, comprising a processor and a memory, wherein the memory is configured to store computer programs capable of running on the processor, and the processor is configured to call and run the computer programs stored in the memory to:
select measurement units and obtain a unit failure rate of chips at a same test position in each measurement unit respectively;
judge whether the unit failure rate of the chips at the same test position of each measurement unit meets a first abnormality condition;
judge whether a test sequence for measurement units meeting the first abnormality condition meets a second abnormality condition when the unit failure rate of the chips at the same test position of any one measurement meets the first abnormality condition; and
a determine that the probe card is abnormal when the test sequence for the measurement units meeting the first abnormality condition meets the second abnormality condition.

8. The apparatus for judging the abnormality of the probe card of claim 7, wherein the processor is further configured to:
select the measurement units and detect failed chips in each measurement unit respectively;
obtain a number of the failed chips at the same test position in each measurement unit; and
calculate the unit failure rate of the chips at the same test position in each measurement unit according to the number of the failed chips at the same test position in each measurement unit and a number of all tested chips at the same test position.

9. The apparatus for judging the abnormality of the probe card of claim 7, wherein the processor is further configured to:
judge whether the unit failure rate of the chips at the same test position of each measurement unit is greater than or equal to a preset failure rate threshold; and
determine that the unit failure rate of the chips at the same test position of each measurement unit meets the first abnormality condition when the unit failure rate of the chips at the same test position of each measurement unit is greater than or equal to the preset failure rate threshold.

10. The apparatus for judging the abnormality of the probe card of claim 7, wherein the processor is further configured to:
obtain a test sequence for the measurement units meeting the first abnormality condition;
judge whether the test sequence is continuous; and
determine that the test sequence for the measurement unit meeting the first abnormality condition meets the second abnormality condition when the test sequence is continuous.
